(19) United States
(12) Patent Application Publication
(10) Pub. No.: US 2011/0046768 A1
(43) Pub. Date: Feb. 24, 2011

(54) Determining Characteristics of Electric Cables Using Terahertz Radiation

(76) Inventors: Robert John Rayzak, Toronto (CA); Mark Stephen Kemper, Adrian, MI (US)

Correspondence Address: Byrne Poh LLP, 11 Broadway, Ste 865, New York, NY, 10004, US

(21) Appl. No.: 12/934,973

(22) PCT Filed: Mar. 27, 2009
(86) PCT No.: PCT/CA2009/000389

§ 371 Date: Oct. 27, 2010

(30) Foreign Application Priority Data
Mar. 27, 2008 (CA) 2627261

(51) Int. Cl. G06F 19/00; B29C 47/02; C23C 16/52

(52) U.S. Cl. 700/103; 702/23; 118/665; 427/8

(57) ABSTRACT

An apparatus, system and method are described for determining a characteristic of an electric cable using THz radiation. The THz radiation may non-destructively penetrate a carbon black semiconductor layer to detect a THz spectrum of a cross-linked polyethylene insulator. The THz spectrum can be analyzed to determine the characteristics of the electric cable, including concentrations of polar chemical by-products in the XLPE insulator and, and to control the production process of the electric cables.

### TECHNICAL FIELD

The system and method described herein relates generally to the production of electric cables with chemically cross linked polyethylene insulators and more particularly to determining characteristics of the electric cables.

### BACKGROUND

In a cross linked polyethylene XLPE insulated power cable a high current flows through a central conductor and the XLPE insulation surrounding the conductor is subjected to high temperatures and a temperature gradient. The maximum temperature typically occurs adjacent to the central conductor and under normal conditions will be approximately 90 degrees C. on a continual basis and approximately 130 degrees C. under overload conditions. The polyethylene is cross linked to provide sufficient mechanical strength to withstand the high temperatures without breaking down which could cause short circuits, arcing, melting, etc.

A chemical process is the most commonly used method to cross link the polymer. However, chemical cross linking of polyethylene, which may use cross linking initiators such as dicumyl peroxide, creates by products such as acetophenone, cumyl alcohol, alpha methyl styrene, methane, ethane and water. The polar compounds among these by products, for example acetophenone and cumyl alcohol, can affect the distribution of the electrical characteristics in the XLPE insulator and influence the results of tests performed to check the high voltage capability of the electric cables prior to installation.

As the volatile polar cross linking by products diffuse out of the polymer its dielectric strength decreases. By the time the insulation is relatively free of such by products its dielectric strength is significantly lowered. Because the cable user, as well as the manufacturer, needs to know the ultimate lowest strength of the cable insulation the general practice is to decrease the concentration of the volatile cross linking by products from the newly manufactured cables before they are commissioned into service.

The concentrations of the volatile cross-linking by-products may be decreased by treating (conditioning) the cable for a period of time, for example several days, at a high temperature in an oven. This procedure is called degassing. Cables, or samples of cables are tested after production to check the integrity of the electric cable and the ultimate user conducts acceptance tests before energizing the cables. Cable manufacturers may use various methods to determine the concentrations of by-products in an electric cable.

The cable manufacturing process involves several stages of mechanical and thermal treatments. For XLPE cables, the insulating material is extruded onto the conductor: the cable enters the extrusion process whereby the initiator is introduced and induces polymer cross-linking. A triple extrusion process used worldwide extrudes simultaneously an inner semiconductive layer, the insulation and an outer semiconductive layer onto a conductor.

Electric cable described herein consists of a conductor, for example aluminum or copper, covered by several insulation layers. A typical cable has two shield layers of a semiconductor material. The first layer is applied onto the conductor to damp impulse currents over the cable. The second layer shields the insulation and reduces surface voltage to zero. The extruded shields are usually made of the same polymer as the insulation with addition of carbon black particles to provide the requisite semiconductivity. The semiconductor layers include carbon black in order to modify the electrical characteristics of the layer. The carbon black semiconductor layer makes measurement of by-products of the insulator layer difficult.

For electric cable manufacturing the insulation material may be supplied as solid polyethylene (PE) pellets that are converted to the insulation by extrusion. The insulation and semiconductive shields may be extruded onto the conductor simultaneously. To achieve the properties desired for the cable insulation the polyethylene is usually cross-linked with added peroxides as initiators. When the extrusion is complete the cable enters the curing stage with elevated temperatures where the peroxide decomposes and induces the cross-linking. Before being wound on a take-up reel the cable passes through a cooling zone where the insulation solidifies.

A common by-product analysis method used by manufacturers is to weigh the sample cable at successive times under heat to measure the loss of the undesirable by-products. Although this method gives a general indication of the amount of by-products released from the electric cable, it gives no direct measure of individual by-products to a manufacturer or user.

A method of determining the concentrations of by-products of a cable in a laboratory is to cut off pieces of the cable after some stage of the high temperature treatment, extract the by-products from the polymer for several hours and then analyze them with a mass spectrometer. This method is cumbersome and time consuming and not suited for use in a production environment.

A thermoluminescence method can provide a measurement of the total concentration of cross-linking by-products in power cable insulation. The instrument must be placed outside of a treatment oven and measures through a window in the oven into a section destructively cut into the cable's outer semiconductor layer.

Another commonly used measurement method is FT-IR (Fourier Transform-Infra Red). This method is laboratory-based whereby pieces are taken from the body of the XLPE under consideration for analysis. However, there is no means to interface an FT-IR system to a remote electric cable sample in, for example, a cable manufacturer's conditioning oven. Furthermore, FT-IR measures only a small amount of sample which may bring into question the representative nature of such measurements of bulk materials such as the ones under consideration for XLPE cable.

Raman spectroscopy has been successfully demonstrated as a method capable of detecting and measuring some organic compounds. The technique involves the use of a laser that is employed to excite the material under examination. The subject compound emits radiation that is shifted in wavelength from the original incident energy. The resulting output is a spectrum that displays the shifted radiation as peaks. The frequency position of the resulting peaks relative to the incident laser is indicative of the functional groups present in the subject material. This provides the basis for qualitative identification of the species in the material. Moreover, the intensities of the peaks are directly related to the concentrations of the individual compounds present in the subject material. This provides the basis for quantitative determination of the species in the material. The output of such a Raman spectrographic test is a spectrum showing the intensity and frequency bands of components.

Several different types of cable manufacturing lines are used in the industry. They can be vertical, horizontal or catenary configurations. A typical line is divided into several zones: each zone is kept at a constant temperature during the production process.

A need therefore exists for producing an apparatus, system and method for measuring characteristics of electrical cables.

### SUMMARY

An embodiment of the present disclosure comprises an apparatus for determining characteristics of an electric cable. The apparatus comprises a radiation source to produce radiation for passing through at least a portion of a cross section of a cross-linked polyethylene (XLPE) insulator of the electric cable, a radiation detector to detect the radiation produced by the radiation source after passing through at least the portion of the cross section XLPE insulator of the electric cable, and an instrument computer coupled to the radiation detector to analyse the detected radiation and determine at least one characteristic of the electric cable.

A further embodiment of the present disclosure comprises a system for producing an electric cable comprising a conductor and a chemically cross-linked polyethylene insulator. The system comprises an extruder for extruding polyethylene (PE) over the conductor, a curing section for heating the extruded PE and a chemical cross-linking initiator to cause the PE to chemically cross-link to form an XLPE insulator over the conductor, a conditioning oven for conditioning the XLPE insulator until a concentration of one or more by-products of the chemical cross-linking reaction is below a threshold, and an apparatus for determining characteristics of an electric cable for determining at least one characteristic of the electric cable.

A further embodiment of the present disclosure comprises a method of producing an electric cable. The method comprises extruding polyethylene (PE) over a conductor, introducing a cross-linking initiator into the PE, curing the extruded PE to activate the cross-linking initiator to cause the extruded PE chemically cross-link to form an XLPE insulator layer over the conductor, and determining at least one characteristic of the electric cable using radiation.

A further embodiment of the present disclosure comprises a system for controlling the production of an electric cable. The system comprises a processor for executing instructions and a memory coupled to the processor for storing instructions for execution by the processor. The executed instructions configuring the computer to receive a THz radiation spectrum of the XLPE electric cable being produced, analyze the received spectrum to determine a characteristic of the electric cable being produced, and generate at least one output signal to control at least one process variable based on the determined characteristic of the electric cable.

### BRIEF DESCRIPTION OF THE DRAWINGS

The illustrative embodiments will be further understood from the following description with reference to the drawings in which:

FIG. 1. is a schematic of an illustrative THz radiation apparatus for use in an electric cable production process;

FIG. 2a depicts an arrangement of a THz apparatus for detecting one or more by-products in an XLPE insulator;

FIG. 2b depicts an arrangement of a THz apparatus for imaging a conductor in an XLPE insulator;

FIG. 3 depicts in a schematic illustrative components of a system for producing an XLPE electric cable in accordance with the present disclosure;

FIG. 4 depicts in a schematic illustrative components of a system for conditioning XLPE electric cables in accordance with the present disclosure;

FIG. 5 depicts in a schematic illustrative components of a computer for controlling an electric cable production process; and

FIG. 6 depicts in a flow chart an illustrative method of producing an XLPE electric cable.

### DETAILED DESCRIPTION

Described herein is a novel use of terahertz (THz) radiation in the production of electric cables. The THz radiation may be used for non-destructive penetration of carbon black semiconductor layers and spectroscopy of chemically cross-linked polyethylene (XLPE) insulators of electric cables, for example high voltage (HV) electric cables. The measurements obtained by the spectroscopy of the XLPE insulator may be used to determine concentrations of polar by-products of the XLPE insulator, including, for example, acetophenone and cumyl alcohol. These measurements may be used to determine characteristics of the electric cable, such as their suitability for deployment for transmission of electricity. The measurements may also be used to control process variables of the cable manufacturing process. THz radiation may be used to improve the measurement of XLPE insulator polar by-products concentrations, the measurement of individual and aggregate concentrations of polar by-product concentrations, the imaging and locating of the conductor of the electric cable, the thickness of the XLPE insulator or semiconductor layers, the delamination of layers of the electric cable, the product quality control and the throughput of the manufacturing process as well as the design of such manufacturing processes.

The illustrative embodiments described herein may be useful to manufacturers of XLPE insulated electric cables and to their end users and suppliers, for example power transmission and distribution companies and electric cable distributors. The illustrative embodiments described herein may also be useful to testing agencies for testing electric cables or samples of electric cables.

In the production of XLPE electric cables, process variables, such as the concentration of cross-linking initiators, the extrusion rate, the conditioning temperature and the conditioning time may affect the final quality of the produced electric cable. As described further herein, THz radiation may be used in situ during the manufacturing process to non-destructively measure one or more by-products of the insulator even when the insulator is covered by a carbon black loaded semiconductor layer. The by-product measurements may be used to control one or more of the process variables. Using the THz radiation technology of the illustrative embodiments measurements can be made in situ and by non-destructively penetrating outer semiconductor layers of the XLPE insulator of the electric cable while the electric cable is in the extrusion line.

The time taken for measurement of the individual by-product concentrations is small compared to the time required for changes in the process variables, for example the cross-linking and formation of associated by-products of the polyethylene (PE) affected by the process variables' controls such as temperature, pressure and peroxide feed rate, etc. Moreover, measurements of the polar by-products may be completed in approximately 2 minutes with the THz radiation instrument of the illustrative embodiments. During this time only a few meters of cable will typically have passed through the extruder and vulcanizing stages which are typically of a length 50 meters or more for HV cable production. Thus, control can be practical in real time, or near real time, and a production run can be modified without loss of any significant length of cable in a typical production run.

In the production of XLPE for cable industries the exact proportions of by-products realized in the manufacturing process depend on at least one of the temperature of the insulator as it is extruded on to the conductor, the pressure of the insulator as it is extruded on to the conductor, the rate at which the insulation is extruded and the rate the cross-linking initiator is simultaneously introduced, the concentration of the cross-linking initiator, the rate at which the cross-linking initiator decomposes. The correct time, temperature and pressure profile through the system is important to maintain.

When the cross-linking is completed the insulation should have an approximate constant level of by-products throughout its thickness given a uniform distribution of peroxide at extrusion (in practice the concentration of polar by-products varies in a parabolic shape radially from inside to outside the cable's cross section geometry). This distribution will change with time after cross-linking as these by-products diffuse out of the cable depleting the exposed layers first.

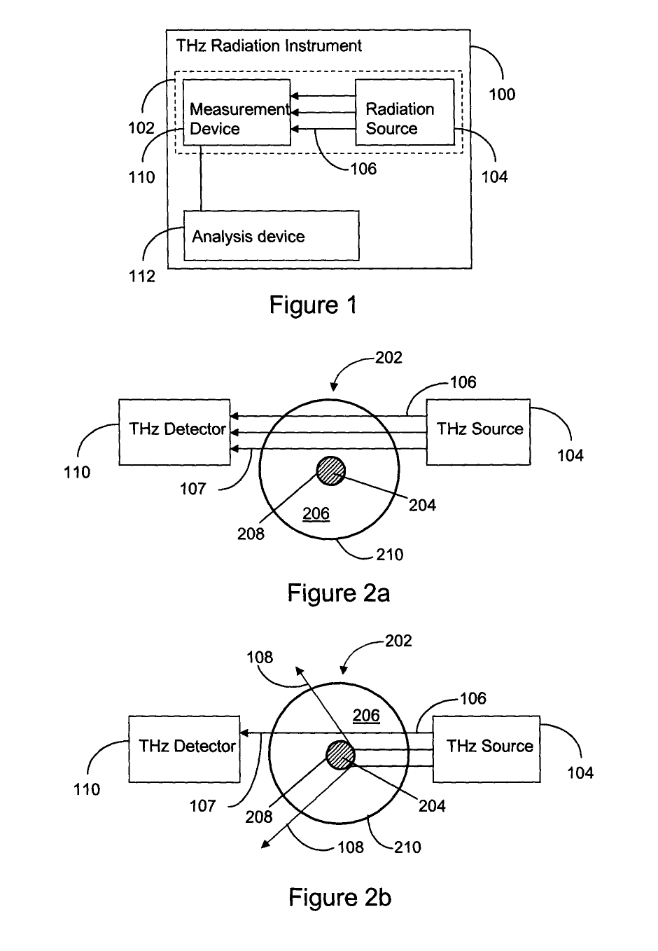

FIG. 1 depicts in a block diagram illustrative components of a THz radiation instrument 100. The THz radiation instrument 100 comprises a radiation source 104 and a measurement device 110, which may collectively be referred to as a sensor 102. The sensor 102 may be used to perform spectroscopy of an electric cable (not shown) by passing radiation 106 from the source 104 through the electric cable to the measurement device 110 which measures the radiation 106 and passes the information to an analysis device 112 which may determine the spectrum of the electric cable. The analysis device 112 may be a computer or other similar device and may be referred to as an instrument computer. The THz radiation instrument 100 is depicted as having a single sensor 102; however, as described further herein the THz radiation instrument 100 may include a plurality of sensors 102 controlled by a single analysis device 112. Furthermore it should be recognized that the sensor 102 and the analysis device do not need to form a single physical unit, but instead the sensor 102 may be located away from the analysis device 112, with the measurement information being communicated in various ways, such as over cables, wires, over a network or wirelessly.

FIG. 2a depicts in a schematic an illustrative arrangement for measuring polar by-products of an XLPE insulator of an electric cable 202. The THz radiation instrument 100 of FIG. 1, including the instrument computer, may be used. However FIG. 2a depicts the arrangement of the sensor 102, with the instrument computer 112 not shown. It is understood that the radiation detector 110 is coupled to the instrument computer 112 which processes the measurement information and determines one or more characteristics of the electric cable 202 being examined. The THz radiation 106 of the THz radiation source 104 is positioned to penetrate the electric cable 202 which comprises an electrical conductor 204 surrounded by an insulator 206. The electric cable may also include an outer skin 210 which may comprise a carbon black rich semiconductor. The electric cable 202 may also include an semiconductor inner layer 208 between the conductor 204 and the insulator 206. The transparency of the semiconductor layers 208,210 to the THz radiation 106 may be varied. The transparency of the semiconductor layers 208,210 to the THz radiation 106 may be based on the temperature of the semiconductor layers 208,210 as further described herein.

To perform THz spectroscopy the THz radiation 106 passes through the outer semiconductor layer 210, if present, and then the XLPE insulator 206. The THz detector 110 detects the radiation 107 after passing through the electric cable 202, and communicates the measurement information to the instrument computer 112 of FIG. 1, which may calculate concentrations of polar by-products present in the insulator 206. The concentrations of the polar by-products may be determine based on, for example the detected THz radiation spectrum of the XLPE insulator of the electric cable. THz frequencies are from approximately 10¹¹-10¹³ Hz.

FIG. 2b depicts in a schematic an illustrative arrangement for imaging a conductor with in an XLPE insulator of an electric cable 202. The arrangement is similar to that described with regards to FIG. 2a; however, the electric cable 202 is positioned relative to the THz radiation source 104 and the THz radiation detector 110 so that the THz radiation 106 is directed at the conductor 204. The conductor 204 reflects and/or scatters the THz radiation 110 that is coincident with it. The THz detector 110 detects the resultant THz radiation 107 which may be used by the instrument computer 112 of FIG. 1 to determine the characteristics of the conductor 204 and insulator 206 using spectroscopy or other analytical methods.

Further, because of the differential transmission, reflection and scattering characteristics of conductors 204, semiconductors layers 208,210 and XLPE insulation 206, the THz radiation instrument 100 may be used to detect separation or delamination of the layers of the electric cable from each other. The layers of the electric cable may include the conductor 204, the insulation 206. the inner semiconductor 208 and the outer semiconductor layer 210. The THz radiation instrument 100 may also be used to detect the presence of water within the XLPE insulator 206. Water, which is a by-product of the polyethylene cross-linking process, may form in the XLPE insulation 206 in the shape of a tree branch. The water will inhibit the passage of the THz radiation passing through the electric cable 107, allowing the THz radiation instrument 100 to detect the presence of the water tree in the XLPE insulator 206 of the electric cable 202. Furthermore, the detected radiation may be used to determine the location of the conductor 204 within the insulator 206.

The radiation source 104 and radiation detector 110 have been described as being separate components; however it is understood that the radiation detector 110 and the radiation source 104 may form a single component. If the radiation source 104 and radiation detector 110 form a single component it may be used to detect radiation reflected from, for example, the semiconductor or the conductor.

In all of these cases of spectroscopy, conductor imaging, conductor and semiconductor imaging, and water tree imaging the measurements may be performed using the THz radiation instrument 100 by the non-destructive penetration with THz radiation of the semiconductor layers when they are present. The semiconductor layers may be formed from a similar material as the insulator, such as polyethylene, however with carbon black particles added to alter the electrical properties of the material. Alternatively the semiconductor layers may be formed from other materials.

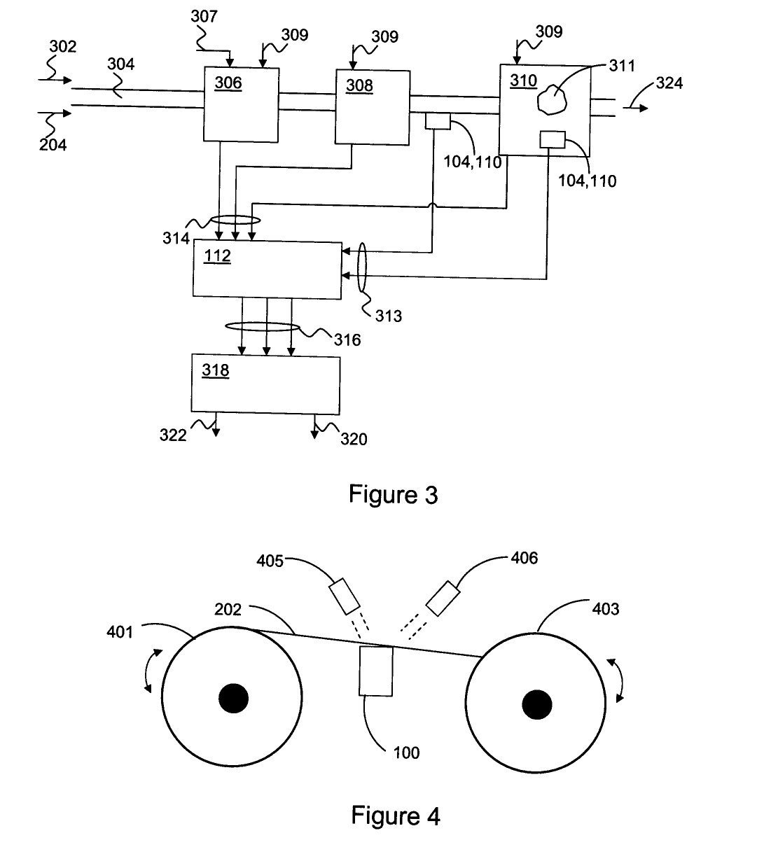

FIG. 3 shows a schematic of a production process for manufacturing a chemically cross-linked polyethylene insulated electric cable using THz radiation. The process includes the extrusion of polyethylene (PE) 302 onto a conductor 204. The extrusion may be carried out by an extruder 304. The conductor 204 with the extruded PE 302 is fed into a preparation stage 306 where cross-linking initiators 307 are added to the extruded PE 302 in order to begin the chemical cross-linking of the PE 302. Alternatively, the cross-linking initiators 307 may be added to the PE as the it is being extruded, or the PE may be premixed with the cross-linking initiators 307 prior to being introduced into the extrusion process.

The conductor 204 and extruded PE 302 with the initiators 307, are fed to a hot section of a continuous curing or vulcanizing tube 308 where the elevated temperatures cause the chemical cross-linking of the PE 302 to proceed to form a XLPE insulator about the conductor 204. The conductor 204 with the XLPE insulator is fed to an oven 310 for conditioning of the XLPE insulator. The oven 310 heats the cable comprising the conductor 204 and the XLPE insulator. The elevated temperatures of the electric cable, comprising the conductor 204 and the XLPE insulator, drives by-products of the chemical cross-linking process out of the XLPE insulator. Once the concentration of by-products are at an acceptable level, the electric cable may be ready for delivery to a consumer or for use 324.

The above description has described the extrusion of PE and chemical conversion to an XLPE insulator on a conductor. For the clarity of description, it does not describe the extrusion of the semiconductor layers 208,210 of FIGS. 2a,b. As is understood by those of ordinary skill in the art, the manufacturing process of the electric cables may also include the extrusion of two semiconductor layers, in addition to the XLPE insulator. The inner semiconductor layer may be extruded onto the conductor 204 and between the conductor 204 and insulator. The outer semiconductor layer 210 of FIGS. 2a,b may be extruded on top of the insulator as it is being extruded from the PE 302. Both semiconductor layers may be formed from the same material as the insulator layer; however they may further include added carbon black particles to alter the layers' electrical characteristics to form a semiconductor.

The XLPE electric cable manufacturing process also uses a THz radiation instrument 100 of FIG. 1 to measure by-products of the XLPE insulator. The THz radiation instrument 100 may provide real time, or near real time measurements of by-products of the XLPE insulator. The measurements of by-products may be fed to an instrument computer 112 of the THz radiation instrument 100 as measurement information 313. The instrument computer 112 may also receive process variable inputs 314 from the cable manufacturing process, such as the rate of extrusion, the temperature at various points in the manufacturing process and the concentration of initiators. As depicted in FIG. 3, a plurality of THz radiation sensors 102 may be used to provide measurement information 313 to the instrument computer 112 from various locations in the manufacturing process. One THz radiation sensor is shown as being placed in the conditioning oven 310, where the temperature within the conditioning oven aids in the penetration of the carbon black semiconductor layers by the THz radiation, as further described herein.

The THz radiation instrument 100 uses THz radiation to measure the concentration of polar by-products, including acetophenone and cumyl alcohol, of the XLPE insulator through THz spectroscopy. The THz radiation penetrates the carbon black loaded semiconductor layers, when present, in order to measure the polar by-products of the XLPE insulator through spectroscopy. The THz radiation instrument 100 may comprise the THz radiation source 104 of FIG. 1, the THz radiation detector 110 of FIG. 1 and the instrument computer 112 of FIG. 1. The THz radiation source generates radiation in the THz frequencies that can penetrate the carbon black of the semiconductor layer. The THz detector detects the THz radiation after passing though at least a portion of a cross section of the electric cable. The resulting detected THz spectrum may be used to determine the polar by-products of the XLPE insulator. The measurements may also be used to image the conductor, insulator, semiconductors, as well as water within the XLPE insulator.

The instrument computer 112 may also control the THz radiation sources 104, receive measurement information from the THz radiation detectors 110 through signals or wires represented as connections 313 in FIG. 3. The instrument computer 112 may also receive process information via signals or wires represented as connections 314 in FIG. 3. The process information may include information regarding the process variables, including extrusion rate, initiator concentration, extrusion temperature, extrusion pressure, conditioning temperature, conditioning pressure and conditioning time. The instrument computer 112 may use the inputs 313,314 for calculating the concentration of polar by-products. The concentration of the polar by-products may be forwarded to a control computer 318 for controlling the manufacturing process. The instrument computer 112 may also forward the process information to the control computer 318. Additionally or alternatively the control computer 318 may receive process information directly as opposed to being forwarded from the instrument computer 112.

The control computer 318 may use the concentration of by-products determined by the instrument computer 112, as well as other information forwarded by the instrument computer 112 such as the process information, or received from other sources, to control the process variables of the manufacturing process. As depicted in FIG. 3, the control computer 318 includes two outputs 322, 320 that are used to control two process variables 307, 309. The output 322 may control the initiator concentration 307 introduced into the PE layer, and the output 320 may control the pressure of the extrusion, curing and conditioning processes 309. It is understood that the control computer 318 may use the inputs 316 to control one or more process variables and is not limited to controlling the initiator concentration and the pressure. FIG. 3 depicts controlling the pressure of the extrusion, curing and conditioning processes via a single process variable control 309 through the output signal 320. It is understood that the control computer 318 may control the pressures individually.

As described above the electric cable being examined by the THz instrument 100 may comprise one or more layers of a semiconductor that includes carbon black particles. The carbon black particles appear opaque to certain electromagnetic wavelengths. However, the transparency of the carbon black semiconductor layers to the THz radiation is dependent upon the resistivity of the carbon black semiconductor layer. The transparency of the semiconductor layer to THz radiation increases as the resistivity of the semiconductor layer increases. Advantageously for the production of electric cables, the resistivity of the carbon black semiconductor layer increases with temperature. As a result as the temperature of the cable increases, the carbon black semiconductor layer becomes more transparent to THz radiation. The manufacturing process of the electric cables may result in high enough temperatures to make the semiconductor layers sufficiently transparent to THz radiation. The temperature of the process may be high enough depending on where the measurement is taken within the manufacturing process. Alternatively or additionally the process may heat the electric cable in the location of the measurement in order to make the semiconductor layer sufficiently transparent to THz radiation to perform spectroscopy, conductor imaging or water tree imaging. For example a heat gun or similar heating element may be used to locally heat a section of the electric cable under measurement. A cooling element may subsequently be used to return the electric cable segment to the normal temperature of the manufacturing process.

The THz instrument 100 described above may be used in an electric cable manufacturing process to provide in situ non-destructive measurement of polar by-products of the XLPE insulator of the electric cables and automatically feed process variable information and detection information to a control device that assesses this information, which may include for example, temperature(s) and concentration(s) of by-product(s) from the cross-linking of the PE insulator. The control device, which may include an instrument computer 112 and/or a control computer 318 as described above, may use the information and make adjustments to process control variables for example using outputs 320,322 to revise pressure settings 309 and cross-linking chemical concentrations 307. It is understood that the control device may asses the information and control additional, or fewer, process variables in the production of the electric cables. The control computer outputs 320, 322 may be used to control directly the process variables in an automated fashion, or may be used indirectly to manually control the process variables through a process operator.

The measurement and control methods of the illustrative embodiments allow XLPE production processes to control the process variables in real time or near real time based on one or more characteristics measured in situ by the THz instrument 100 of FIG. 1. The THz radiation instrument 100 may be placed within the electric cable production line to assess the by-products as the cable is being produced. The measurement of the by-products by the THz instrument 100 may take approximately two minutes allowing the near real time control of the manufacturing process.

Additionally or alternatively the THz radiation instrument 100 may be placed in the conditioning or degassing oven to measure the concentration of the by-products over the course of degassing, which may take, for example, several days. The measurement of the concentrations of the XLPE insulator polar by-products by non-destructively penetrating the semiconductor layer(s) allows the degassing process to be stopped once a desired concentration has been reached within substantially the entire length of the electric cable.

Referring to FIG. 4 there is depicted an illustrative system 400 for use in a degassing oven. The system 400 comprises two reels for spooling and unspooling the electric cable onto and off of. A first reel 401 feeds/receives a length of electric cable 202 to a second reel 403 which receives/feeds the length of cable 202 from/to the first reel 401. The length of cable 202 between the two reels 401,403 can be monitored continually by a THz instrument 100 of FIG. 1, or the sensor 102 of the THz instrument 100. The transparency of the carbon black loaded semiconductor layer to THz radiation is dependent upon at least the temperature of the semiconductor layer. In order to raise the resistivity of the semiconductor outer layer on the length of cable 202 a heater 405 may be used if necessary to aid in measurement taking by making the semiconductor outer layer more transparent to THz radiation. To reduce the cable temperature back to that of the oven a cooler 406 may be employed. The temperature of the degassing oven may be sufficient so that a heater and cooler are not necessary. After an appropriate time when the polar by-products concentrations are determined to be at an acceptable level the back and forth movement of the cable 202 between the two reels 401, 403 can be stopped after all the cable is back on one of the two reels. In such a manner the polar by-products concentrations in substantially the entire length of cable will be known, and as such the quality of the cable can be determined with greater certainty.

The two reel 401,403 arrangement described above allows substantially an entire length of the electric cable 202 to pass under the THz radiation instrument 100, or the THz radiation sensor 102 of the THz instrument 100. It is understood that other arrangements are possible to pass the cable under the THz radiation instrument 100, or the THz radiation sensor 102 of the THz instrument 100.

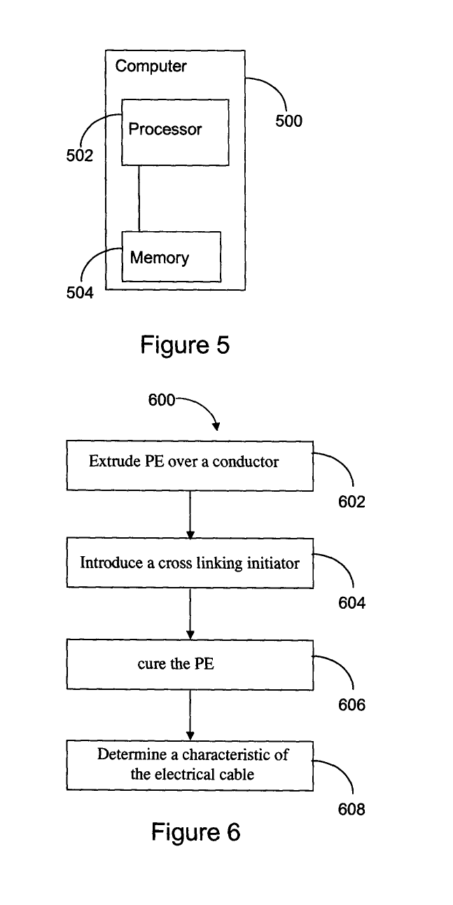

FIG. 5 depicts in a schematic illustrative components of a computer for controlling the production process of the electric cable. The computer 500 comprises a processor 502 for executing instructions. The processor may include one or more central processing units (CPU), CPU cores, microprocessors, application specific integrated circuits (ASICs), field programmable gate arrays (FPGAs). The processor 502 is coupled to a memory 504 for storing instructions to be executed by the processor 502. The instructions stored in the memory 504 configure the processor of the computer 500 to control the manufacturing process. The computer 500 receives as input a signal from a THz sensor and analyses the input to determine a concentration of at least on by-product of an XLPE insulator of an electric cable and produces as an output a signal for controlling at least one process variable.

FIG. 6 depicts in a flow chart a method of producing an electric cable. The method 600 comprises extruding polyethylene (PE) over a conductor (602), introducing a cross-linking initiator into the PE (604), curing the extruded PE to activate the cross-linking initiator to cause the extruded PE to chemically cross-link to form an XLPE insulator layer over the conductor (606), and determining at least one characteristic of the electric cable using radiation(608).

While particular aspects of the illustrative embodiments have been shown and described, changes and modifications may be made to such embodiments without departing from the scope of the invention. For example, more than one instrument and computer can be used to have measurements made and assessed in a stage-wise manner along the production process. Also, measurement of other chemically cross-linked polymers in an in situ, continuous and on-the-fly basis in other production processes may be used in conjunction with illustrative embodiments. The THz radiation instrument may also be used advantageously in XLPE cable production to monitor and control the production of XLPE electric cable that do not have an outer layer comprising a carbon black semiconductor.

### Experimental Testing of the THZ Instrumentation

When a THz spectrum is obtained experimentally from an attempted analysis of components in a given electric cable sample the THz spectrum must be analyzed to derive useful information from the spectrum.

Moreover, a THz spectrum does not intrinsically provide individual wt % concentrations of any component. In order to see if practical concentration information could be obtained from experimental results, it is necessary to calibrate the spectral information against gas chromatography-mass spectrometry (GC/MS) data for the sample. By doing so, a mathematical model could be created in conjunction with the instrument software. These mathematical constructions include, but are not necessarily restricted to, integration of peaks exhibiting frequencies known to be representative of the components of interest. Computation of the wt % of each polar component may be achieved by calibrating the peak areas so-obtained against the GC/MS data for the same specimen(s) which may be for example a calibration sample or samples. The information obtained from the calibration sample or samples may then be used to determine wt % of electric cables under examination in situ.

THz radiation has previously been used in the tire industry to determine the adhesion of the tire components. The THz radiation was able to penetrate the carbon black present in the tire compound, as well as determine the adhesion of the tire compound with the other tire components, for example steel belts.

Results of experiments performed on samples of commercially available high voltage (HV) electric cables shows that the THz radiation instrument described herein is able to penetrate carbon black semiconductor materials and can obtain spectra of polar by-products in the XLPE insulator. Raman spectroscopy was used to verify the presence of the polar compound acetophenone in the electric cable.

The experimental results also confirm the beneficial increase in resistivity of the carbon black semiconductors with temperature.

Commercial carbon black semiconductor materials (carbon black in XLPE from 30 wt % to 40 wt %) from cable manufacturers were used to demonstrate penetration of THz radiation through the carbon black semiconductor layer. Previous measurement techniques have been unable to penetrate the carbon black semi conductor layer, preventing analysis of XLPE insulators through the semiconductor outer layer.

The ability of THz radiation to penetrate any medium is dependent on the resistivity (and thereby resistance) of the medium. Further, elevated temperature which serves to increase the resistivity of a medium such as a carbon black semiconductor enhances the ability of THz radiation to penetrate through the semiconductor into the XLPE cable insulation.

A material is typically considered to be transparent to THz radiation if its resistivity is greater than 10,000 ohm-centimeters. Semiconductors have been measured at varying temperatures by heat gun and ohm meter. In the case of a particular sample its room temperature resistance of 600 ohms is driven to 30 Kohms with 110 C temperature, using a heat gun. In production practice a lesser temperature could set the semiconductor to a resistivity that causes the carbon black semiconductor layer to be sufficiently transparent to THz radiation in order to perform spectroscopy of the XLPE insulator.

The following discussion illustrates the result of heating on the reflectivity of a commercial carbon black semiconductor measured by THz instrument. Measured was reflectivity rather than resistivity as a practical matter to protect the THz instrument's probe from possible accidental excessive heat in the laboratory environment. Resistivity is inversely related to reflectivity; however, so we can draw resistivity conclusions from the reflectivity data.

A demonstration of the behavior of THz reflectivity by heating and cooling of the semiconductor sample is: At time t=0 seconds the reflectivity is seen at room temperature to be 550 units as heat begins to be applied. The reflectivity decreases dramatically to approx. 210 units in 60 seconds at which point the heat gun was repositioned so there is less heat applied to the semiconductor sample. This causes the reflectivity to rise to about 450 units at approximately 100 seconds. More heat was then applied to suppress the reflectivity to 350 units at 250 seconds. At this time the heat gun was turned off. The reflectivity of the semiconductor climbed to its starting room temperature value of 550 units as the semiconductor cooled gradually from 250 to 650 seconds.

The experiment shows by THz measurement that semiconductor resistivity/reflectivity increases/decreases with increasing temperature as we would have expected from the resistance versus temperature tests by heat gun and ohm meter. It was further seen that the resistivity/reflectivity returns to its room temperature value when its temperature does.

THz radiation can penetrate through a carbon black semiconductor and heat can aide in this penetration by increasing the resistivity of the carbon black semiconductor and so its transparency to the THz radiation.

Not all carbon black loaded materials respond identically in proportion to the wt % content of carbon black. Styrene Butadiene Rubber tire material is approximately 50% carbon black by weight. Its resistivity is essentially infinite and so THz radiation readily passes through it. On the other hand, an XLPE sample loaded with 30 wt % to 40 wt % carbon black is not fully transparent to THz radiation. The transparency of the carbon black to the THz radiation can be enhanced as the experiments have shown.

### THz Spectroscopy and XLPE

Once the THz radiation has penetrated beyond the carbon black semiconductor surrounding the XLPE cable insulation it can identify and quantify the polar compounds contained therein through THz spectroscopy. Cumyl alcohol and acetophenone are polar compounds and are amenable to analysis by THz spectroscopy

The in-line operating benefits of THz radiation technology of the exemplary embodiments in XLPE cable production will provide great value for production control, product development and knowledge of the state of degassing of an entire length of XLPE cable

THz spectroscopy data were taken from a commercial sample of XLPE cable approximately 5 mm thick. The acetophenone spectrum shows one major acetophenone THz spectrum peak of 2.5 absorbance at approximately 1.3 THz as well as a peak of approximately 0.5 absorbance at 0.5 THz.

No attempt was made to quantify and calibrate these data. Such calibration of the data may be performed by corroborating the THz spectroscopy data with by-product concentration information obtained independently, for example using GC/MS.

A THz spectrum was attempted to be taken from a very thin (1 mm) XLPE sample; however no indication of spectrum peaks in the region 0.5 THz to 1.5 THz were seen as were detected for the 5 mm thick sample of XLPE. A possible explanation to this failure of THz radiation to detect the by-products in the 1 mm sample is that there are scant by-products remaining in the thin sample due to the ease of degassing from a thin sample. Another is that the detection ability of the THz radiation is insufficient because of the thin sample.

The detection ability of THz radiation depends on the volume of material observed by the THz radiation. This volume is determined by the THz radiation ray diameter and the length of the ray's passage through the XLPE. It could be that the 1 mm thickness of the “thin” piece of XLPE is not thick enough. This thickness matter is not of concern in XLPE cable production where cable diameters can be several centimeters.

The time taken to capture the spectrum was approximately 2 minutes. This is adequately fast in light of the slow progress of XLPE electric cable through an extrusion unit (typically 3 m./min) where several thousand meters of cable may be produced in a continual length.

THz Radiation and Identification of Conductors within the XLPE

A characteristic of THz radiation is that it is reflected or scattered by strong electrical conductors (low resistance or resistivity). Thus, it is possible for THz radiation to “see” the conductor inside a cable. Because of the different transmission, reflection and scattering properties of THz radiation by XLPE insulation, semiconductors and imbedded conductors THz radiation could be used to see if the insulation, semiconductors and conductors are delaminating or are not correctly positioned in the cable

An experiment showed a THz image of a metal insert placed into a commercial sample of XLPE. Another experiment showed no THz image of a metal insert when the metal insert was not present in an XLPE sample.

A metal insert was press fitted into a block of XLPE and THz radiation attempted to pass through the XLPE in the region of the metal insert. The data for the XLPE block without metal insert show a level of the THz amplitude passing through the XLPE block to be much greater than the THZ amplitude passing through the XLPE sample of an XLPE block with the metal insert. For example, in the range of THz frequency 1.5 THz to 3.5 THz the THz amplitude passing through is 3.941 to 10.64 without the metal insert. However, with the metal insert the THz amplitude passing through the PE is only 0.4428 to 1.997. This shows significant attenuation and scattering of the THz radiation caused by the metal insert.

Because the semiconductors, conductors and insulators of XLPE cable have differing resistivity, absorbance and transmissive characteristics it will be possible to detect the various layers in a cable by THz radiation of the exemplary embodiments. This allows determination of location and delamination of these constituents relative to each other within an electric cable, by non-destructive penetration of the carbon black semiconductor outer layer by THz radiation using the illustrative embodiments described herein.

1. An apparatus for determining characteristics of an electrical cable comprising:
a radiation source to produce radiation for passing through at least a portion of a cross section of a cross linked polyethylene (XLPE) insulator of the electrical cable;
a radiation detector to detect the radiation produced by the radiation source after passing through at least the portion of the cross section XLPE insulator of the electrical cable; and
an instrument computer coupled to the radiation detector to analyse the detected radiation and determine at least one characteristic, including a concentration of at least one polar by product, of the XLPE insulation of the electrical cable.

2. The apparatus as claimed in claim 1, wherein the at least one characteristic of the electrical cable comprises a delamination of layers of the electrical cable.

3. The apparatus as claimed in claim 1, wherein the at least one characteristic of the electrical cable comprises a presence of water within the XLPE insulator of the electrical cable.

4. The apparatus as claimed in claim 1, wherein the at least one characteristic of the electrical cable comprises a thickness of layers of the electrical cable.

5. The apparatus as claimed in claim 1, wherein the at least one characteristic of the electrical cable comprises a location of a conductor within the XLPE insulator of the electrical cable.

6. The apparatus as claimed in claim 1, wherein the radiation source produces radiation in the terahertz (THz) frequencies in the range of 1011-1013 Hz.

7. The apparatus as claimed in claim 6, wherein the radiation source produces the radiation in the THz frequencies to pass through an outer carbon black loaded semiconductor layer of the electrical cable.

8. The apparatus as claimed in claim 7, wherein the outer carbon black-loaded semiconductor layer comprises polyethylene loaded with carbon black.

9. The apparatus as claimed in claim 1, further comprising a control computer for controlling a process of producing the electrical cable based on at least the determined characteristic of the electrical cable.

10. The apparatus as claimed in claim 1, wherein the at least one characteristic of the electrical cable is determined from the electrical cable in situ during production of the electrical cable.

11. The apparatus as claimed in claim 1, wherein the concentration of the at least one polar by product is determined from the electrical cable while the electrical cable is in a conditioning oven.

12. The apparatus as claimed in claim 9 when dependent upon claims 9 and 6, wherein the control computer analyses a THz radiation spectrum of the XLPE insulation comprising the at least one polar by-product to determine a weight percentage of the at least one polar by product in the XLPE insulator of electrical cable.

13. The apparatus as claimed in claim 12, wherein the control computer identifies a plurality of polar by products of the XLPE insulation of the electric cable using the THz radiation spectrum of the XLPE insulator of the electrical cable.

14. The apparatus as claimed in claim 1, wherein the at least one polar by product of the XLPE insulation comprises at least one of:
acetophenone; or
cumyl alcohol.

15. The apparatus as claimed in claim 1, wherein the determined characteristic of the electrical cable is used to determine an end point has been reached in the production of the electrical cable.

16. The apparatus as claimed in claim 9, wherein the control computer controls at least one process variable of the production of the electrical cable comprising at least one of:
a concentration of a chemical cross linking initiator;
a pressure of the extrusion of the electrical cable;
a rate of extrusion of the electrical cable;
a temperature of a curing stage in the production of the electrical cable;
a pressure of the curing stage in the production of the electrical cable;
a temperature of a conditioning oven in the production of the electrical cable; or
a length of time of conditioning of the electrical cable in the conditioning oven.

17. The apparatus as claimed in claim 7, wherein the radiation source produces the THz radiation to pass through the outer carbon black loaded semiconductor layer of the electrical cable non-destructively.

18. A system for producing an electrical cable comprising a conductor and a chemically cross linked polyethylene insulator, the system comprising:
an extruder for extruding polyethylene (PE) over the conductor;
a curing section for heating the extruded PE and a chemical cross linking initiator to cause the PE to chemical cross link to form an XLPE insulator over the conductor;
a conditioning oven for conditioning the XLPE insulator until a concentration of one or more by products of the chemical cross linking reaction is below a threshold; and
an apparatus as claimed in claim 1 for determining at least one characteristic of the electrical cable.

19. The system as claimed in claim 18, wherein the chemical cross linking initiator is introduced into the PE prior to extruding the PE.

20. The system as claimed in claim 18, wherein the chemical cross linking initiator is introduced into the PE simultaneously with extruding the PE.

21. The system as claimed in claim 18, wherein the chemical cross linking initiator is introduced into the PE after extruding the PE.

22. A method of producing an electrical cable comprising:
extruding polyethylene (PE) over a conductor;
introducing a cross linking initiator into the PE;
curing the extruded PE to activate the cross linking initiator to cause the extruded PE chemically cross link to form an XLPE insulator layer over the conductor; and
determining at least one characteristic of the electrical cable, including a concentration of at least one polar by product of the XLPE insulation of the electrical cable, using radiation.

23. The method as claimed in claim 22, wherein the radiation is terahertz (THz) with frequencies in the range of 1011-1013 Hz.

24. The method as claimed in claim 22, wherein introducing the cross linking initiator into the PE comprises one of:
introducing the cross linking initiator into the PE prior to extruding the PE over the conductor;
introducing the cross linking initiator into the PE simultaneously with extruding the PE over the conductor; or
introducing the cross linking initiator into the PE after extruding the PE over the conductor.

25. The method as claimed in claim 22, wherein determining the at least one characteristic of the electrical cable comprises determining a delamination of layers of the electrical cable.

26. The method as claimed in claim 22, wherein determining the at least one characteristic of the electrical cable comprises determining a presence of water within the XLPE insulator of the electrical cable.

27. The method as claimed in claim 22, wherein determining the at least one characteristic of the electrical cable comprises determining a thickness of layers of the electrical cable.

28. The method as claimed in claim 22, wherein determining the at least one characteristic of the electrical cable comprises determining a location of a conductor within the XLPE insulator of the electrical cable.

29. The method as claimed in claim 24, further comprising conditioning the XLPE insulator until the concentration of the at least one polar by product is below a threshold.

30. The method as claimed in claim 22, wherein determining the at least one characteristic of the electrical cable is carried out in situ and further comprises:
analysing the at least one characteristic of the electrical cable; and
controlling at least one process variable based on the analysed characteristic of the electrical cable.

31. The method as claimed in claim 25, wherein determining the concentration of the at least one polar by product of the XLPE insulator is carried out when the electrical cable is being conditioned, and further comprises:
analysing the determined concentration of the at least one polar by product; and
stopping the conditioning of the electrical cable when the concentration of the at least one polar by product is below the threshold throughout substantially an entire length of the electrical cable.

32. The method as claimed in claim 23, further comprising extruding an outer semiconductor layer over the XLPE insulator and wherein the THz radiation penetrates the outer semiconductor layer of the electric cable.

33. The method as claimed in claim 24, further comprising analysing a THz radiation spectrum of the XLPE insulator comprising the at least one polar by-product to determine a weight percentage of the at least one polar by-product in the XLPE insulator of the electrical cable.

34. The method as claimed in claim 33, further comprising identifying a plurality of polar by-products in the XLPE insulator of the electric cable.

35. The method as claimed in claim 24 wherein the at least one polar by-product of the XLPE insulator comprises at least one of
acetophenone; or
cumyl alcohol.

36. The method as claimed in claim 30, wherein controlling the at least one process variable comprises at least one of:
controlling a concentration of the chemical cross linking initiator;
controlling a pressure at which the extrusion of the XLPE electrical cable is carried out;
controlling a rate at which the extrusion of the PE layer over the conductor is carried out;
controlling a temperature at which the curing is carried out;
controlling a pressure at which the curing is carried out;
controlling a temperature at which the conditioning of the electrical cable is carried out; or
controlling a length of time of conditioning of the electrical cable.

37. The method as claimed in claim 22, further comprising using the transmission, reflection and scattering characteristics of THz radiation directed through at least a portion of a cross section of the XLPE insulator of the electric cable to image a position of the conductor of the electrical cable relative to the XLPE insulator.

38. The method as claimed in claim 22, further comprising using the transmission, reflection and scattering characteristics of THz radiation directed through at least a portion of a cross section of the XLPE insulator of the electric cable to image the position of the outer semiconductor layer relative to the XLPE insulator.

39. The method as claimed in claim 29, wherein the outer semiconductor layer comprises a carbon black loaded material.

40. The method as claimed in claim 39, wherein the carbon black loaded material is carbon black polyethylene which has been chemically cross linked to form a carbon black loaded XLPE semiconductor.

41. The method as claimed in a claim 39, further comprising heating the carbon black loaded semiconductor layer to raise the resistivity of the carbon black loaded semiconductor layer and raise the transparency of the carbon black loaded semiconductor layer to the THz radiation.

42. The method as claimed in claim 22, wherein the at least one characteristic of the electrical cable is determined non-destructively using the radiation.

43. A system for controlling the production of a chemically cross linked polyethylene (XLPE) electrical cable comprising:
a processor for executing instructions;
a memory coupled to the processor for storing instructions for execution by the processor, when executed by the processor the instructions configuring the computer to:
receive a THz radiation spectrum of the XLPE electrical cable being produced;
analyze the received spectrum to determine a characteristic of the electrical cable being produced; and
generate at least one output signal to control at least one process variable based on the determined characteristic of the electrical cable.

44. (canceled)

45. (canceled)
